(19) United States
(12) Patent Application Publication
(10) Pub. No.: US 2013/0221414 A1
(43) Pub. Date: Aug. 29, 2013

(54) Semiconductor FET and Method for Manufacturing the Same

(71) Applicants: Chao Zhao, Kessel-lo (BE); Jun Luo, Beijing (CN); Huicai Zhong, San Jose, CA (US)

(72) Inventors: Chao Zhao, Kessel-lo (BE); Jun Luo, Beijing (CN); Huicai Zhong, San Jose, CA (US)

(21) Appl. No.: 13/697,319

(22) PCT Filed: Mar. 26, 2012
(86) PCT No.: PCT/CN2012/000377

§ 371 Date: Nov. 9, 2012

(30) Foreign Application Priority Data
Feb. 27, 2012 (CN) CN201210045350.0

(51) Int. Cl. H01L 29/78; H01L 21/336

(52) U.S. Cl. 257/288; 438/299; 257/E29.255; 257/E21.409

(57) ABSTRACT

The present invention provides a semiconductor FET and a method for manufacturing the same. The semiconductor FET may comprise: a gate wall; a fin outside the gate wall, both ends of the fin being connected with the source/drain regions on both ends of the fin; and a contact wall on both sides of the gate wall, the contact wall being connected with the source/drain regions via the underlying silicide layer, wherein an airgap is provided around the gate wall. Since an airgap is formed around the gate wall, and particularly the airgap is formed between the gate wall and the contact wall, it is possible to decrease the parasitic capacitance between the gate wall and the contact wall. As a result, the problem of excessive parasitic capacitance resulting from use of the contact wall can be effectively alleviated.

### FIELD OF THE INVENTION

The present invention generally relates to a semiconductor technology, and more particularly to a semiconductor Field Effect Transistor (FET) and a method for manufacturing the same.

### BACKGROUND OF THE INVENTION

With progress in the semiconductor technology, Metal Oxide Semiconductor Field Effect Transistors (MOSFETs) with new structures have been developed continuously by the skilled person in the art. For example, Intel Corporation announced in 2011 that a tri-gate structure would be used in the 22 nm technical node. This three dimensional or 3-D transistor structure is also called as a fin FET (FinFET) or multiple gate (Multi-gate) FET.

As for these three dimensional transistor structures, it is required to modify the contact accordingly. The reason lies in that a FinFET is very small in size, and the process complexity would greatly increase if the separate cylindrical contact plug in the planar device is stilled adopted. The contact plug may become a contact wall by a contact structure of planar wall type, and it is possible to greatly reduce process complexity, reduce cost, and increase yield of product. A structural view of the contact plug and the contact wall which has been used in the prior art is shown in FIG. 1.

However, when the contact wall is used to replace the contact plug, a problem occurs in which a enormous parasitic capacitance will generated between the contact wall and the gate wall, thus contributing to RC delay of the whole circuit and disadvantageously affecting performance improvement of the semiconductor device such as FinFET. Therefore, it is an urgent issue to reduce the parasitic capacitance.

### SUMMARY OF THE INVENTION

In view of this, the present invention provides a semiconductor FET and a method for manufacturing the same, which is capable of addressing or at least alleviating some drawbacks in the prior art.

According to a first aspect of the present invention, it is provided a semiconductor FET, which may comprise:

a gate wall;
a fin outside the gate wall, both ends of the fin being connected with the source/drain regions on both ends of the fin; and
a contact wall on both sides of the gate wall, the contact wall being connected with the source/drain regions via the underlying silicide layer,
wherein an airgap is provided around the gate wall.

In an embodiment of the present invention, the airgap provided around the gate wall may comprise an airgap between the gate wall and the contact wall.

In another embodiment of the present invention, the airgap between the gate wall and the contact wall may comprise an airgap between the gate wall and an insulating layer around the contact wall.

In yet another embodiment of the present invention, the airgap provided around the gate wall may comprise an airgap between the gate wall and an insulating layer surrounding the fin, the source/drain regions, the silicide layer, and the contact wall.

In an embodiment of the present invention, the gate wall may further comprise a first spacer surrounding the gate wall.

In another embodiment of the present invention, the airgap provided around the gate wall may comprise an airgap between the first spacer and the contact wall.

In yet another embodiment of the present invention, the airgap between the first spacer and the contact wall may comprise an airgap between the first spacer and an insulating layer around the contact wall.

In still another embodiment of the present invention, the airgap provided around the gate wall may comprise an airgap between the first spacer and an insulating layer surrounding the fin, the source/drain regions, the silicide layer, and the contact wall.

In an embodiment of the present invention, the material for forming the first spacer may comprise a material with a low dielectric constant such as amorphous carbon nitride thin film, polycrystalline boron nitride thin film, or fluorinated silicate glass.

In another embodiment of the present invention, the airgap is vacuum or the airgap is filled with a gas with a low dielectric constant.

In yet another embodiment of the present invention, the gas with a low dielectric constant may comprise air or an inert gas.

According to a second aspect of the present invention, it is provided a method for manufacturing a semiconductor FET, which may comprise the steps of:

forming a fin on a semiconductor substrate, source/drain regions on both ends of the fin, a spacer, a gate wall surrounded by the spacer, and a silicide layer on the source/drain regions;
forming an insulating layer on the silicide layer, spacer, and gate wall;
forming in the insulating layer a contact trench penetrating the insulating layer, the contact trench being filled with a metal to form a contact wall which is connected with the underlying silicide layer;
planarizing the contact wall and the insulating layer to expose a tip of the spacer; and
removing the spacer via the exposed tip of the spacer to form an airgap around the gate wall.

In an embodiment of the present invention, after the step of forming the insulating layer on the silicide layer, the spacer, and the gate wall and before the step of forming the contact trench, the method may further comprise a step of planarizing the insulating layer.

In another embodiment of the present invention, the step of removing the spacer via the exposed tip of the spacer to form the airgap around the gate wall may comprise:

removing the spacer by wet etching or UV light irradiation.

In yet another embodiment of the present invention, removing the spacer may comprise completely removing the spacer.

In still another embodiment of the present invention, the step of forming the spacer may comprise:

forming a first spacer surrounding the gate wall and a second spacer surrounding the first spacer.

In an embodiment of the present invention, the step of removing the spacer via the exposed tip of the spacer to form the airgap around the gate wall may comprise:

removing the second spacer by wet etching or UV light irradiation.

In another embodiment of the present invention, removing the second spacer may comprise completely removing the second spacer.

In yet another embodiment of the present invention, the material for forming the first spacer may comprise a material with a low dielectric constant such as amorphous carbon nitride thin film, polycrystalline boron nitride thin film, or fluorinated silicate glass, the material for forming the second spacer may have a selective etching rate different from that of the material of the first spacer, or the material of the second spacer may be an organic material with a low dielectric constant.

In still another embodiment of the present invention, the airgap may be vacuum or the airgap may be filled with a gas with a low dielectric constant. Alternatively, the gas with a low dielectric constant may comprise air or an inert gas.

By means of the semiconductor FET and the method for manufacturing the same of the present invention, a novel semiconductor FET structure is obtained, in which an airgap is form around the gate wall, and especially an airgap is formed between the gate wall and the contact wall. Due to the existence of this airgap, the value of dielectric constant in the parasitic capacitance formula is reduced, thus greatly reducing the value of parasitic capacitance between the gate wall and the contact wall. As a result, the problem of excessive parasitic capacitance resulting from use of the contact wall can be effectively alleviated.

### BRIEF DESCRIPTION OF THE DRAWINGS

The above and other features of the present invention will be more apparent from the embodiments shown in the accompanying drawings, in which:

FIG. 1 schematically shows a contact plug and a contact wall used for a fin FET (FinFET) structure in the prior art.

FIG. 2 schematically shows a view of a semiconductor FET structure according to an embodiment of the present invention.

FIG. 3 schematically shows a view of a variation of the semiconductor FET structure shown in FIG. 2.

FIG. 4 schematically shows a view of a semiconductor FET structure according to another embodiment of the present invention.

FIG. 5 schematically shows a view of a variation of the semiconductor FET structure shown in FIG. 4.

FIGS. 6A-6E schematically show the process flow for manufacturing a semiconductor FET.

### DETAILED DESCRIPTION OF EMBODIMENTS

Firstly, it should be noted that terms regarding position and orientation in the present invention, such as “above”, “below”, “left” and “right” etc, refer to the direction as viewed from the front of the sheet in which the drawings are located. Therefore, the terms “above”, “below”, “left” and “right”, etc regarding position and orientation in the present invention only indicate the relative positional relationship in cases as shown in the drawings. They are presented only for purpose of illustration, rather than limiting the scope of the present invention.

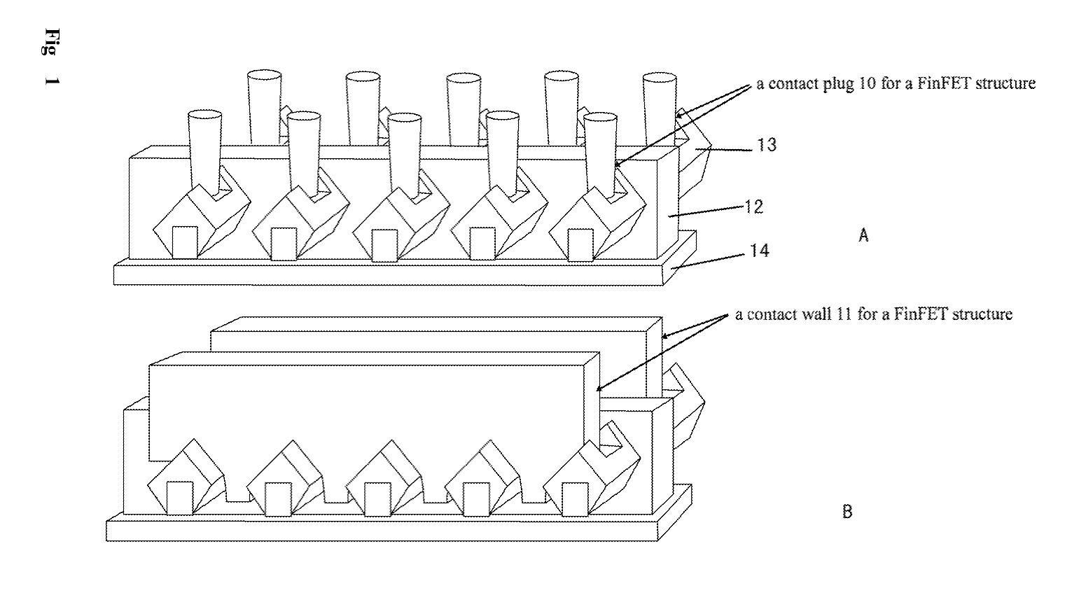

FIG. 1 schematically shows a contact plug and a contact wall used for a fin FET (FinFET) structure in the prior art. FIG. 1A shows a contact plug 10 for a FinFET structure known in the prior art. The contact plug 10 is located above the source/drain regions 13, and the gate wall 12 lies between a plurality of contact plugs 10. Both the contact wall 12 and the source/drain regions 13 are located on a common substrate 14. FIG. 1B shows a contact wall 11 for a FinFET structure known in the prior art. The contact plug in FIG. 1A is replaced by a contact wall. The the contact plug 10 and the contact wall 11 in a FinFET structure is known in Kuhn et al. in IEDM2008, and is not described in detail herein.

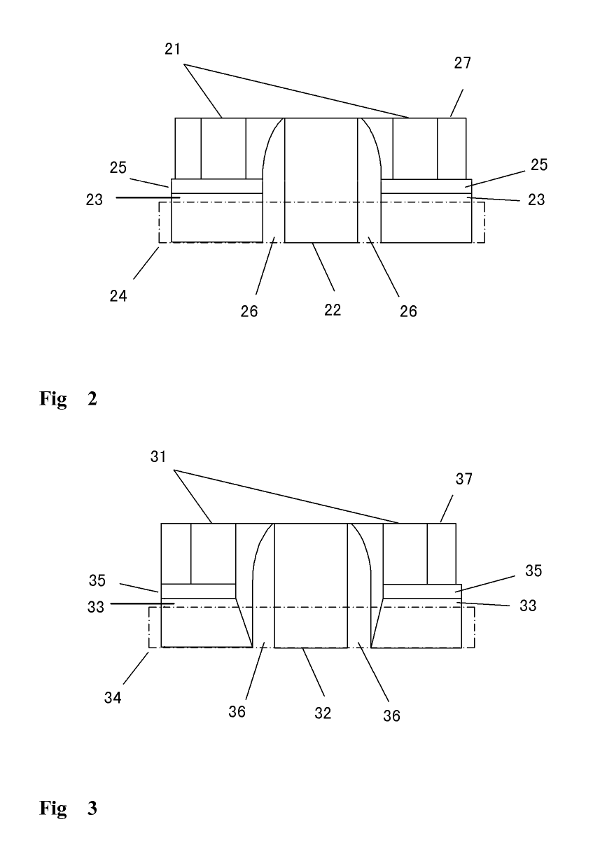

Hererinafter, the semiconductor FET structure and the method for manufacturing the same of the present invention will be described in detail with referring to FIGS. 2-6 of the present invention. Si substrate is illustrated in FIGS. 2-6 as an example. In addition to Si substrate, it is also possible to use any suitable semiconductor substrate such as SiGe substrate, SOI (silicon on insulator) substrate, etc. Therefore, the present invention is not limited to Si substrate.

FIG. 2 schematically shows a view of a semiconductor FET structure according to an embodiment of the present invention. A MOSFET of FinFET structure is illustrated as an example in FIG. 2. Of course, the MOSFET of a FinFET structure only serves as an example, and the skilled person in the art will appreciate that the present invention can also be applied to other devices, such as a tri-gate MOSFET, a gate-all-around MOSFET, a MOSFET of a vertical structure, a planar double gate MOSFET, or the like. As shown in FIG. 2, the MOSFET of a FinFET structure comprises a gate wall 22; a fin 24 outside the gate wall 22, both ends of the fin 24 being connected with source/drain regions 23 on both ends of the fin 24; a contact wall 21 on both sides of the gate wall 22, the contact wall 21 being connected with the source/drain regions 23 via the underlying silicide layer 25; and an airgap 26 provided around the gate wall 22. Alternatively, the airgap 26 provided around the gate wall 22 may comprise the airgap 26 between the gate wall 22 and the contact wall 21. Alternatively, the airgap 26 between the gate wall 22 and the contact wall 21 may comprise the airgap 26 between the gate wall 22 and an insulating layer 27 around the contact wall 21. FIG. 2 illustrates a case in which the contact wall 21 is surrounded by the insulating layer 27, and the spacer formed around the gate wall 22 is completely removed to form the airgap 26.

Hereinafter, reference is made to FIG. 3, which schematically shows a view of a variation of the semiconductor FET structure shown in FIG. 2. The semiconductor FET structure shown in FIG. 3 differs from the structure shown in FIG. 2 in the shape of source/drain regions 33. The skilled person in the art will appreciate that during the process of forming a gate wall comprising a gate oxide (a gate dielectric layer) and a metal gate (a gate electrode) by performing wet etching, depositing, etc. in the middle of the fin 34, the etching process in the prior art usually leads to source/drain regions 33 with inclined side-surfaces. In the structure shown in FIG. 3, the source/drain regions 33 have inclined left and right side-surfaces. As a result, during the subsequent process of depositing an insulating layer 37, the insulating layer 37 will cover the fin 34, the source/drain regions 33, the left and right side-surfaces of a silicide layer 35, and will cover the periphery of a contact wall 31. Therefore, once the spacer (now shown) around the gate wall 32 is completely removed, an airgap 36 is formed between the gate wall 32 and the insulating layer 37 on the fin 34, the source/drain regions 33, the silicide layer 35, and the left and right sides of the contact wall 31. During the manufacturing process, the structure in FIG. 3 may be a more common case than what is shown in FIG. 2.

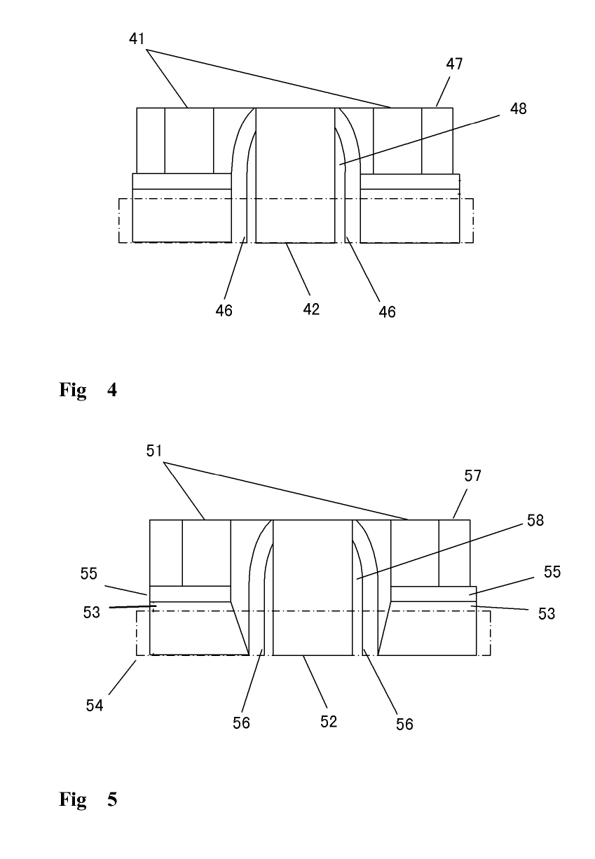

FIG. 4 schematically shows a view of a semiconductor FET structure according to another embodiment of the present invention. Compared with the structure shown in FIG. 2, a gate wall 42 has a first spacer 48 surrounding the gate wall 42 in the FinFET MOSFET shown in FIG. 2. Therefore, in the final structure, an airgap 46 around the gate wall 42 comprises the airgap 46 between the first spacer 48 and the contact wall 41. Since the contact wall 41 in FIG. 4 is surrounded by an insulating layer 47, the airgap 46 between the first spacer 48 and the contact wall 41 comprises the airgap 46 between the first spacer 48 and the insulating layer 47 around the contact wall 41.

Hereinafter, reference is made to FIG. 5, which schematically shows a view of a variation of the semiconductor FET structure in FIG. 4. The semiconductor FET structure shown in FIG. 5 also differs from the structure shown in FIG. 4 in the shape of source/drain regions 53 and a fin 54. According to description with relation to FIG. 3, the skilled person in the art will appreciate that during the process of forming a gate wall comprising a gate oxide and a metal gate by performing wet etching, depositing, etc in the middle of the fin 54, the etching process in the prior art usually leads to source/drain regions 53 with inclined side-surfaces. In the structure shown in FIG. 5, the source/drain regions 53 have an inclined left and right side-surfaces. As a result, during the subsequent process of depositing an insulating layer 57, the insulating layer 57 will cover the fin 54, the source/drain regions 53, the silicide layer 55, the left and right side-surfaces of a contact wall 51. Therefore, once the second spacer (now shown) around the first spacer 58 is removed, an airgap 56 is formed between the first spacer 58 and the insulating layer 57 on the fin 54, the source/drain regions 53, the silicide layer 55, and the left and right sides of the contact wall 51. Also, during the manufacturing process, the structure in FIG. 5 may be more common than the that shown in FIG. 4.

It is noted that in each embodiment described above, the material for forming the first spacer may comprise silicon nitride thin film, silicon oxide thin film, or other dielectric materials. The airgap may be vacuum, or the airgap may be filled with a gas with a low dielectric constant, which can decrease the parasitic capacitance between the gate wall and the contact wall. Alternatively, the gas with a low dielectric constant may comprise air or an inert gas.

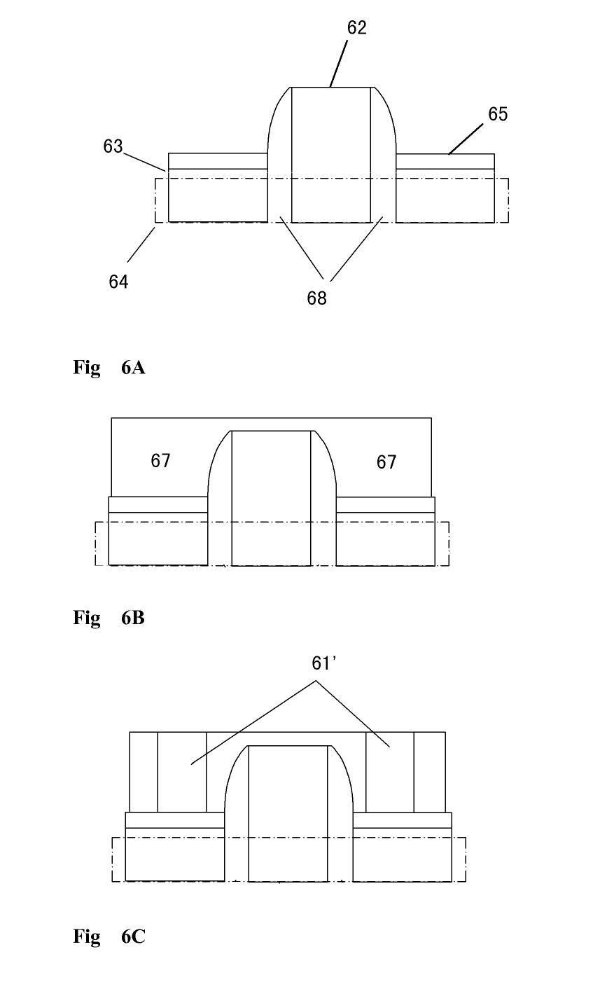

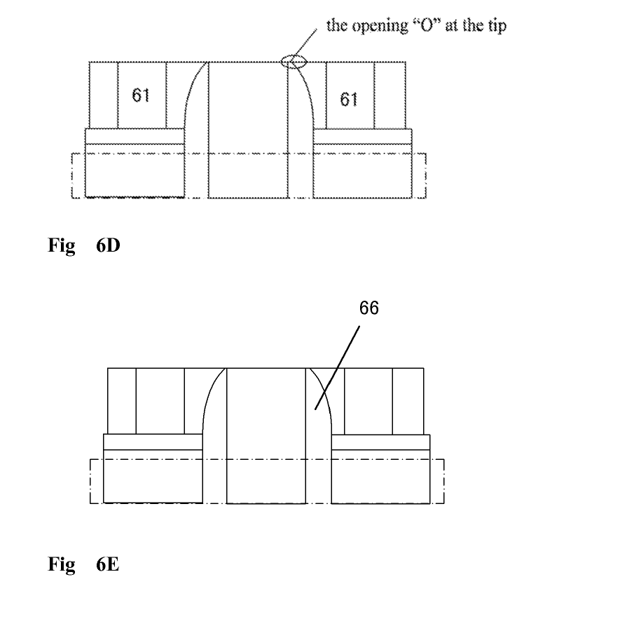

The process flow for manufacturing the semiconductor FET of the present invention will be described in detail hereinafter with reference to FIGS. 6A-6E.

The first step is described with reference to FIG. 6A. A FinFET structure has been formed in FIG. 6A. In the first step, the method may comprise forming, on a semiconductor substrate (not shown), a fin 64, source/drain regions on both ends of the fin 63, a spacer 68, a gate wall 62 surrounded by the spacer 68, and a silicide layer 65 on the source/drain regions. The fin 64 may be formed by forming a Si island on a semiconductor substrate such as Si substrate so as to obtain a thin Si island, i.e. the fin 64. The fin 64 may also be formed by Si nanowires. The source/drain regions 63 formed on both ends of the fin may be formed by doping at both ends of the fin 64. For example, the doping may be realized by performing ion implantation and thermal activation. The source/drain regions 63 may also be source/drain regions formed by full-metal silicide. For example, the full-metal silicide source/drain regions are formed by a full-metallization source/drain process, and then a Schottky barrier is formed between the source/drain regions and the channel by ion implantation doping and thermal treatment. In order to decrease the contact resistance between the contact wall subsequently formed and the source/drain regions 63 which will be formed on the source/drain regions 63, it is preferred that after forming the source/drain regions 63, a metal such as Ni, Co, or Ni—Pt (Pt%≦20%) is deposited on the source/drain regions 63 by means of physical vapor deposition, chemical vapor deposition or atomic layer vapor deposition, and then high temperature annealing is performed, so that the deposited metal reacts with silicon in the source/drain regions, thus forming a silicide layer 65 with a relatively low resistivity. In forming the gate wall 62, preferably, a gate dielectric layer (not shown) and a gate wall may be formed. A high dielectric constant material such as SiO₂, SiON, HfO₂, Al₂O₃, Ga₂O₃, La₂O₃ or combinations thereof may be used to form the gate dielectric layer. For example, in case of SiO₂, it may be formed by thermal oxidation, and can also be formed by chemical vapor deposition or atomic layer vapor deposition. As for SiON or other high dielectric constant materials, they may be formed by chemical vapor deposition, atomic layer vapor deposition, or physical vapor deposition. The gate wall 62 may be formed by polycrystalline Si or a metal gate material by means of chemical vapor deposition, atomic layer vapor deposition, or physical vapor deposition. The spacer 68 may be formed by an inorganic material with a low dielectric constant which can be removed by wet etching, and can also be formed by an organic material with a low dielectric constant which can be removed by UV light irradiation. The above mentioned inorganic material with a low dielectric constant may comprise amorphous carbon nitride thin film, polycrystalline boron nitride thin film, fluorinated silicate glass, etc. The organic material with a low dielectric constant may comprise an aromatic polymer such as polyimide.

The second step is described with reference to FIG. 6B. An insulating layer 67 is formed on the silicide layer 65, the spacer 68, and the gate wall 62. The insulating layer 67 may be formed by SiO₂, SiON, or a porous material with a low dielectric constant, by means of chemical vapor deposition, atomic layer vapor deposition, or physical vapor deposition. Preferably, after forming the insulating layer 67 on the silicide layer 65, the spacer 68, and the gate wall 62, and before subsequently forming a contact trench, the method comprises a planarizing step for planarizing the insulating layer 67.

The third step is described with reference to FIG. 6C. A contact trench 61′ penetrating the insulating layer 67 is formed in the insulating layer 67, and the contact trench 61′ is filled with a metal to form a contact wall connected with the underlying silicide layer 65. The contact wall may be formed in such a manner that a contact trench 61′ penetrating the insulating layer 67 is formed in the insulating layer 67 on the silicide layer 65 corresponding to the source/drain regions by photolithography and etching. Alternatively, the contact wall may comprise a filled metal enclosed by a diffusion barrier layer. For example, prior to filling the contact trench 61′ with a metal, a diffusion barrier layer (not shown) of Ti, TiN, Ti/TiN, Ta, TaN, or Ta/TaN is formed on the inner surface of the contact trench 61′ by means of chemical vapor deposition, atomic layer vapor deposition, or physical vapor deposition, so as to prevent the filled metal from diffusing into the spacer or even into the gate wall. Then, a metal is filled on the surface of the diffusion barrier layer. The filled metal used herein may be W or Cu. The filled W may be formed by chemical vapor deposition or atomic layer vapor deposition. The filled Cu may be formed by depositing a Cu seed layer by physical vapor deposition and then plating.

The fourth step is described with reference to FIG. 6D. The contact wall and the insulating layer are planarized so that the tip of the spacer is exposed. For example, an opening “O” at the exposed tip is shown in FIG. 6D. The gate wall 62 and the spacer 68 surrounding the gate wall 62 appear like a “wall”. In a treatment such as Chemical Mechanical Polishing (CMP), the finishing point of polishing is controlled, so that the tip of the spacer 68 is exposed. The opening “O” at the exposed tip has a shape of narrow and long slit. For example, the opening is a slit with a length of about 5 nm, thus facilitating removing of the spacer 68 from the opening “O” at the tip.

The fifth step is described with reference to FIG. 6E. The spacer 68 is removed through the exposed tip of the spacer, e.g. the opening “O” at the tip, so as to form an airgap 66 around the gate wall 62. The spacer 68 may be removed by wet etching or UV light irradiation. For example, as for the spacer 68 formed by an inorganic material with a low dielectric constant such as silicon oxide, silicon nitride, fluorinated silicate glass, etc., it can be removed by wet etching. As for the spacer 68 formed by an organic material with a low dielectric constant, such as aromatic polymer such as polyimide, UV light irradiation may be used, so that the organic material with a low dielectric constant evaporates through the opening “O” at the tip and thus is removed.

As shown in FIG. 6E, the spacer 68 is completely removed to form the airgap 66 around the gate wall 62. It is noted that the spacer may also be partially removed, so as to form an airgap between the remaining spacer and the contact wall. For example, with reference to FIG. 4 or FIG. 5, during formation of the spacer 68 surrounding the gate wall 62, it is also possible to form a first spacer (not shown) surrounding the gate wall 62 and a second spacer (not shown) surrounding the first spacer. The material for forming the first spacer may comprise a material with a low dielectric constant, such as silicon oxide, silicon nitride, silicon carbide, polycrystalline boron nitride thin film, fluorinated silicate glass, etc., and the material for forming the second spacer has a selective etching rate different from that of the material for the first spacer, or the material for the second spacer is an organic material with a low dielectric constant. Since the second spacer material has a selective etching rate different from that of the material for the first spacer, it is possible to remove the second spacer and retain the first spacer by selective wet etching, so as to form the airgap between the first spacer and the contact wall. Alternatively, if the material for the second spacer is an organic material with a low dielectric constant, the organic material may be irradiated by a UV light, so that it evaporates through the opening “O” at the tip to remove the second spacer, thus forming the airgap between the first spacer and the contact wall. Preferably, removing the second spacer may comprise completely removing the second spacer.

As shown in FIGS. 6A-6E, the left and right side-surfaces of the fin 64 and the source/drain regions 63 are vertical side-surfaces. From the description with relation to FIGS. 3 and 5, the skilled person in the art will appreciate that during the process of forming a gate wall comprising a gate oxide and a metal gate by performing wet etching, depositing, etc. in the middle of the fin 64, the etching process in the prior art usually leads to source/drain regions 63 with inclined side-surfaces. Namely, the source/drain regions 63 may have inclined left and right side-surfaces. As a result, during the process of depositing an insulating layer 67, the insulating layer 67 will cover the fin 64, the source/drain regions 63, the silicide layer 65 and the left and right side-surfaces of the contact wall 61. Therefore, once the second spacer around the first spacer is removed or the spacer is removed, an airgap 66 is formed between the first spacer and the insulating layer 67 on the fin 64, the source/drain regions 63, the silicide layer 65, and left and right side-surfaces of the contact wall 61, or an airgap 66 is directly formed around the gate wall 62. Also, during the manufacturing process, the structure of this variation may be more common than that shown in FIGS. 6A-6E.

In each embodiment as described above, the airgap 66 may be vacuum, or the airgap 66 may be filled with a gas having a low dielectric constant, which may decrease the parasitic capacitance between the gate wall 62 and the contact wall 61. Alternatively, the gas with a low dielectric constant may comprise air or an inert gas.

In the novel semiconductor FET and method for manufacturing the same of the present invention as described above, since an airgap is formed around the gate wall, and particularly the airgap is formed between the gate wall and the contact wall, it is possible to decrease the parasitic capacitance between the gate wall and the contact wall. As a result, the problem of excessive parasitic capacitance resulting from the contact wall can be effectively alleviated.

The shape and height of the fin, the source/drain regions, the silicide layer, the insulating layer, the contact wall, the gate wall, the spacer, the airgap or the like, as shown in FIGS. 2-6 of the present invention, are only exemplary and do not indicate that the relative size among these specific structures follows the scale shown in the drawings. In practice, it is possible that the height of the contact wall occupies a substantial portion of the total height of the fin, the source/drain regions, the silicide layer, and the contact wall, which is not difficult to understand for the skilled person in the art.

Although the present invention has been described with reference to the embodiments which have been contemplated currently, it should be appreciated that the present invention is not limited to the disclosed embodiments. On the contrary, the present invention intends to cover all modifications and equivalents which fall within the spirit and scope of the appended claims. The scope of the appended claims should be interpreted to the broadest extent to cover all these modifications and equivalents.

What is claimed is:

1. A semiconductor Field Effect Transistor (FET), comprising:
a gate wall;
a fin located outside the gate wall, wherein source/drain regions are located on both ends of the fin; and
a contact wall on both sides of the gate wall, the contact wall being connected with the source/drain regions via the underlying silicide layer,
wherein,
an airgap is provided around the gate wall.

2. The semiconductor FET according to claim 1, wherein the airgap provided around the gate wall comprises an airgap between the gate wall and the contact wall.

3. The semiconductor FET according to claim 2, wherein the airgap between the gate wall and the contact wall comprises an airgap between the gate wall and an insulating layer around the contact wall.

4. The semiconductor FET according to claim 1, wherein the airgap provided around the gate wall comprises an airgap between the gate wall and an insulating layer surrounding the fin, the source/drain regions, the silicide layer and the contact wall.

5. The semiconductor FET according to claim 1, wherein the gate wall further comprises a first spacer surrounding the gate wall.

6. The semiconductor FET according to claim 5, wherein the airgap provided around the gate wall comprises an airgap between the first spacer and the contact wall.

7. The semiconductor FET according to claim 6, wherein the airgap between the first spacer and the contact wall comprises an airgap between the first spacer and an insulating layer around the contact wall.

8. The semiconductor FET according to claim 5, wherein the airgap provided around the gate wall comprises an airgap between the first spacer and an insulating layer surrounding the fin, the source/drain regions, the silicide layer, and the contact wall.

9. The semiconductor FET according to claim 5, wherein the material for forming the first spacer comprises a material with a low dielectric constant, including silicon oxide, silicon nitride, silicon carbide, fluorinated silicate glass, etc.

10. The semiconductor FET according to any one of claim 1, wherein the airgap is vacuum, or the airgap is filled with a gas with a low dielectric constant.

11. The semiconductor FET according to claim 10, wherein the gas with a low dielectric constant comprises air or an inert gas.

12. A method for manufacturing a semiconductor FET, comprising:
forming a fin on a semiconductor substrate, source/drain regions on both ends of the fin, a spacer, a gate wall surrounded by the spacer, and a silicide layer on the source/drain regions;
forming an insulating layer on the silicide layer, on the spacer and on the gate wall;
forming a contact trench penetrating the insulating layer in the insulating layer, filling the contact trench with a metal to form a contact wall which is connected with the underlying silicide layer;
planarizing the contact wall and the insulating layer to expose a tip of the spacer; and
removing the spacer via the exposed tip of the spacer to form an airgap around the gate wall.

13. The method for manufacturing a semiconductor FET according to claim 12, wherein after the step of forming the insulating layer on the silicide layer, the spacer, and the gate wall and before the step of forming the contact trench, the method further comprises planarizing the insulating layer.

14. The method for manufacturing a semiconductor FET according to claim 13, wherein the step of removing the spacer via the exposed tip of the spacer to form the airgap around the gate wall comprises:
removing the spacer by wet etching or UV light irradiation.

15. The method for manufacturing a semiconductor FET according to claim 14, wherein removing the spacer comprises completely removing the spacer.

16. The method for manufacturing a semiconductor FET according to claim 12, wherein the step of forming the spacer comprises:
forming a first spacer surrounding the gate wall and a second spacer surrounding the first spacer.

17. The method for manufacturing a semiconductor FET according to claim 16, wherein the step of removing the spacer via the exposed tip of the spacer to form the airgap around the gate wall comprises:
removing the second spacer by wet etching or UV light irradiation.

18. The method for manufacturing a semiconductor FET according to claim 17, wherein removing the second spacer comprises completely removing the second spacer.

19. The method for manufacturing a semiconductor FET according to claims 16, wherein the material for forming the first spacer comprises a material with a low dielectric constant including silicon oxide, silicon nitride, silicon carbide, fluorinated silicate glass, etc., the material for forming the second spacer has a selective etching rate different from that of the material of the first spacer, or the material of the second spacer is an organic material with a low dielectric constant.

20. The method for manufacturing a semiconductor FET according to claim 12, wherein the airgap is vacuum, or the airgap is filled with a gas with a low dielectric constant.

21. The method for manufacturing a semiconductor FET according to claim 20, wherein the gas with a low dielectric constant comprises air or an inert gas.
